(19) United States
(12) Patent Application Publication
(10) Pub. No.: US 2024/0012439 A1
(43) Pub. Date: Jan. 11, 2024

(54) POWER SUPPLY SYSTEM

(71) Applicant: ROHM Co., LTD., Kyoto (JP)

(72) Inventors: Isamu Iwhashi, Kyoto (JP); Hiroki Inoue, Kyoto (JP)

(21) Appl. No.: 18/346,965

(22) Filed: Jul. 5, 2023

(30) Foreign Application Priority Data
Jul. 6, 2022 (JP) 2022-108822

(51) Int. Cl. G05F 1/575

(52) U.S. Cl. CPC G05F 1/575; G11C 17/16

(57) ABSTRACT

Provided is a power supply system including a plurality of linear power supply devices. Each of the linear power supply devices includes an output transistor having a first main electrode that is connectable to an application terminal of an input voltage and a second main electrode that is connectable to a first feedback resistor, the first feedback resistor and a second feedback resistor being connected to each other in series, an error amplifier to which a reference voltage and a feedback voltage that is generated at a node to which the first feedback resistor and the second feedback resistor are connected are input, the error amplifier being capable of driving a control terminal of the output transistor, an output terminal, and an electrode pad.

### CROSS REFERENCE TO RELATED APPLICATIONS

This application claims priority benefit of Japanese Patent Application No. JP 2022-108822 filed in the Japan Patent Office on Jul. 6, 2022. Each of the above-referenced applications is hereby incorporated herein by reference in its entirety.

### BACKGROUND

The present disclosure relates to a power supply system.

In the past, linear power supply devices (linear regulators) that can generate a desired output voltage from an input voltage have been mounted on various applications (automotive onboard equipment, industrial equipment, office equipment, digital home electrical appliances, portable equipment, etc.).

In some linear power supply devices, two linear power supply devices are used, and output terminals for outputting output voltages of the respective linear power supply devices are connected in common to a common load (for example, JP 2020-4214A). That is, such linear power supply devices are connected in parallel to a common load. The purposes of using such linear power supply devices are to disperse heat by breaking down the load current into the output currents output from the output terminals and to increase the load current on the basis of the output current output from each output terminal, for example.

### BRIEF DESCRIPTION OF THE DRAWINGS

FIG. 1 is a diagram illustrating a configuration of a power supply system according to a comparative example;

FIG. 2 is a diagram illustrating a configuration of a linear power supply device according to a reference example;

FIG. 3 is a diagram illustrating a configuration of a power supply system according to an exemplary embodiment of the present disclosure;

FIG. 4 is a diagram illustrating a configuration of a linear power supply device according to a modification example;

FIG. 5 is a diagram illustrating a first configuration example regarding reference voltage adjustment; and

FIG. 6 is a diagram illustrating a second configuration example regarding reference voltage adjustment.

### DETAILED DESCRIPTION

### 1. Comparative Example

Here, before a novel embodiment of the linear power supply device is described, a comparative example will be described for comparison.

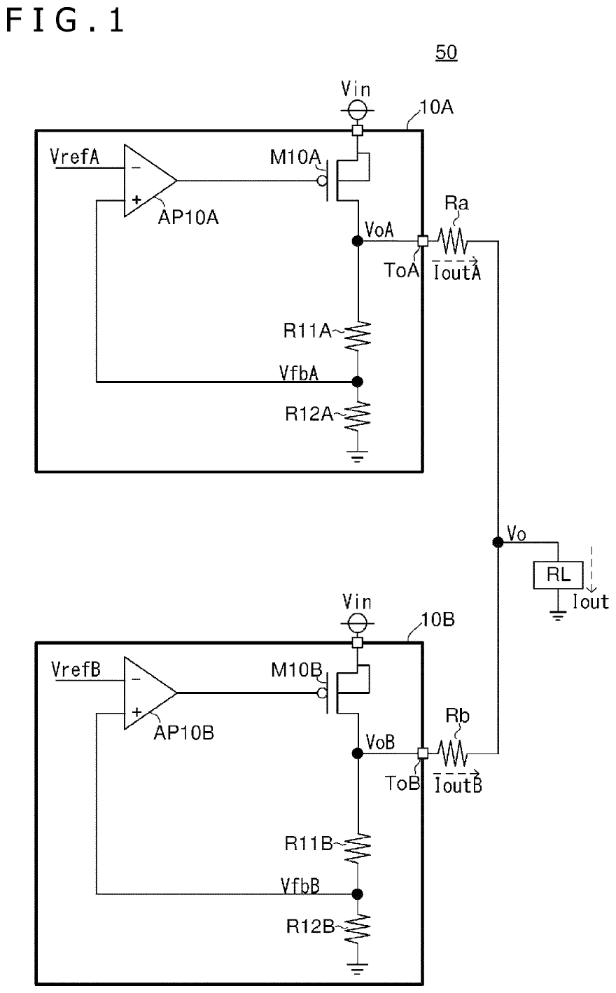

FIG. 1 is a diagram illustrating the configuration of a power supply system 50 according to a comparative example. The power supply system 50 includes a linear power supply device a linear power supply device 10B, and ballast resistors Ra and Rb. The power supply system 50 supplies load currents Iout to a load RL by using two linear power supply devices 10A and

The linear power supply devices 10A and 10B are linear regulators that step down an input voltage Vin to generate desired output voltages VoA and VoB, respectively. Incidentally, the linear power supply device 10A and the linear power supply device 10B are semiconductor integrated circuit (IC) packages having the same configuration, and the corresponding components are illustrated by being denoted by the same reference signs to which “A” or “B” is added. The configuration of the linear power supply device 10A will be described below as a typical example.

As illustrated in FIG. 1, the linear power supply device 10A includes an output transistor M10A, feedback resistors R11A and R12A, and an error amplifier AP10A, which are integrated into one chip and packaged.

A source of the output transistor M10A configured as a p-channel metal-oxide-semiconductor (PMOS) transistor (PMOS field-effect transistor (FET)) is connected to an input terminal of the input voltage Vin. A drain of the output transistor M10A and a first end of the feedback resistor R11A are connected in common to an output terminal ToA for outputting the output voltage VoA. A second end of the feedback resistor R11A is connected to a first end of the feedback resistor R12A. A second end of the feedback resistor R12A is connected to a ground terminal. A non-inverting input terminal (+) of the error amplifier AP10A is connected to a connection node (=application terminal of feedback voltage VfbA) to which the feedback resistors R11A and R12A are connected. An inverting input terminal (−) of the error amplifier AP10A is connected to an application terminal of a reference voltage VrefA. An output terminal of the error amplifier AP10A is connected to a gate of the output transistor M10A.

The above-described error amplifier AP10A performs gate control of the output transistor M10A such that the feedback voltage VfbA (=VoA×{R12A/(R11A+R12A)}) corresponding to the output voltage VoA agrees with the predetermined reference voltage VrefA. That is, the on-resistance value of the output transistor M10A is continuously controlled such that the output voltage VoA agrees with its target value (=VrefA×{(R11A+R12A)/R12A}).

Similarly, in the linear power supply device 10B, the on-resistance value of an output transistor M10B is continuously controlled such that the output voltage VoB agrees with its target value.

The output terminal ToA is connected to a first end of the ballast resistor Ra provided outside the linear power supply devices 10A and 10B. An output terminal ToB is connected to a first end of the ballast resistor Rb provided outside the linear power supply devices 10A and 10B. Second ends of the respective ballast resistors Ra and Rb are connected in common to the load RL. Therefore, the linear power supply devices 10A and 10B are connected in parallel to the common load RL.

Here, although the typical values (Typ values) of the output voltages VoA and VoB of the linear power supply devices 10A and 10B are set to be the same, variations in the linear power supply device may cause the output voltage to vary with respect to the typical value. For example, there is a variation of ±2% with respect to the typical value of 5V. Such variations are caused by, for example, variations in the reference voltage, the feedback voltage, or a threshold voltage of the output transistor, and variations in an input offset voltage of the error amplifier.

In the case of a configuration in which the output terminals ToA and ToB are directly connected to each other, for example, when the output voltage VoA is higher than the output voltage VoB due to variations, the output transistor M10B on the linear power supply device 10B side is kept off, and an output current IoutB is thus not output from the output terminal ToB. Accordingly, the load current Iout is supplied only by an output current IoutA output from the output terminal ToA of the linear power supply device 10A. Therefore, the output current is concentrated in a linear power supply device on one side.

In contrast, in the configuration according to the present comparative example illustrated in FIG. 1, when the output voltage VoA is higher than the output voltage VoB, for example, as the load current Iout gradually increases from 0 A, the output voltage VoA is dropped by the ballast resistor Ra, and an output voltage Vo generated at the node to which the respective second terminals of the ballast resistors Ra and Rb are connected gradually decreases. Then, when the output voltage Vo reaches the output voltage VoB, the output transistor M10B on the linear power supply device 10B side starts operating, and the output current IoutB starts to be output from the output terminal ToB. That is, a parallel operation in which the load current Iout is supplied by both the output currents IoutA and IoutB is started. It should be noted that the ballast resistors Ra and Rb are only required to be set to resistance values such that the voltage drop across each of the resistors is equal to or greater than the voltage difference between the maximum value and the minimum value caused by variations in the output voltage.

Thus, with the configuration of this comparative example, in the case where two linear power supply devices are connected in parallel and used, the parallel operation is possible even when there is variation in the output voltages. However, in the present comparative example, the resistance values of the ballast resistors Ra and Rb are large, and the load regulation (the stability of the output voltage with respect to the load current) is low.

### 2. Reference Example

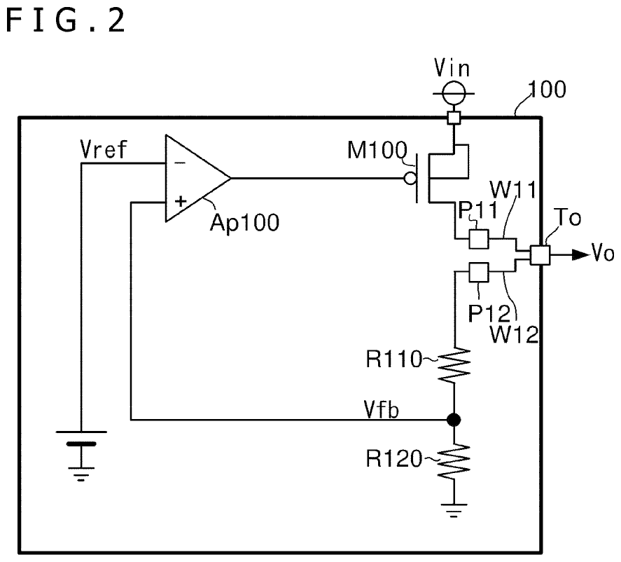

Here, FIG. 2 illustrates the configuration of a linear power supply device 100 according to a reference example. The linear power supply device 100 has a configuration in which an output transistor M100, feedback resistors R110 and R120, and an error amplifier AP100 are integrated and packaged. In the linear power supply device 100, a drain of output transistor M100 is connected to an electrode pad P11. The electrode pad P11 is connected to an output terminal To which is an external terminal via a wire W11. A first end of the feedback resistor R110 is connected to an electrode pad P12. The electrode pad P12 is connected to the output terminal To via a wire W12.

With such a configuration, the output voltage Vo generated at the output terminal To is controlled by feedback through the feedback resistors R110 and R120 in consideration of the voltage drop caused by the current flowing through the output transistor M100 and the impedance of the wire W11, and therefore, the accuracy of the output voltage Vo is improved.

### 3. Embodiment of Present Disclosure

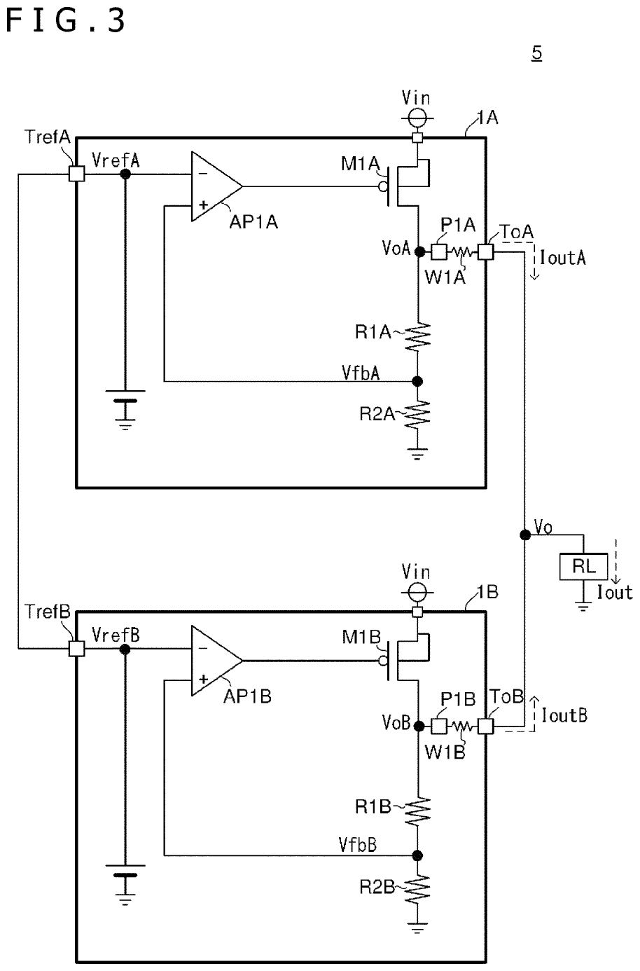

FIG. 3 is a diagram illustrating a configuration of a power supply system 5 according to an exemplary embodiment of the present disclosure. The power supply system 5 has a linear power supply device 1A and a linear power supply device 1B. The linear power supply device 1A and the linear power supply device 1B are semiconductor IC packages having the same configuration, and the corresponding components are illustrated with “A” or “B” added to the same reference signs. The configuration of the linear power supply device 1A will be described below as a typical example.

The linear power supply device 1A has a configuration in which an output transistor M1A, feedback resistors R1A and R2A, and an error amplifier AP1A are integrated and packaged. Further, the linear power supply device 1A also has the output terminal ToA, a reference voltage terminal TrefA, and other terminals as external terminals.

As a difference from the reference example (FIG. 2) described above, in the linear power supply device 1A, a node to which a drain of the output transistor M1A and a first end of the feedback resistor R1A are connected is joined to an electrode pad P1A. The electrode pad P1A is connected to the output terminal ToA via a wire W1A. Also, the application terminal of the reference voltage VrefA input to the error amplifier AP1A is connected to the reference voltage terminal TrefA.

The output terminal ToA of the linear power supply device 1A and the output terminal ToB of the linear power supply device 1B are connected in common to the load RL. That is, the linear power supply devices 1A and 1B are connected in parallel to the load RL.

In the linear power supply device 1A, the output voltage VoA generated at the electrode pad P1A is controlled to agree with its target value (=VrefA×{(R1A+R2A)/R2A}). In the linear power supply device 1B, the output voltage VoB generated at an electrode pad P1B is controlled to agree with its target value (=VrefB×{(R1B+R2B)/R2B}).

It is assumed herein that the output voltage VoA is higher than the output voltage VoB due to variations in the reference voltages VrefA and VrefB. In this case, when the load current Iout starts flowing, the output current IoutB is not output from the output terminal ToB, and the load current Iout is supplied only by the output current IoutA output from the output terminal ToA.

When the load current Iout increases, the voltage at the output terminal ToA drops due to the voltage drop across the wire W1A in the linear power supply device 1A. However, since the impedance of the wire W1A is small, in the case where the difference between the output voltages VoA and VoB is large due to the variation, the voltage at the output terminal ToA may not reach VoB even when the load current Iout reaches a steady state. Therefore, in the configuration of FIG. 3, reference voltage terminals TrefA and TrefB are connected to each other outside the linear power supply devices 1A and 1B. As a result, even if there are variations in the reference voltages VrefA and VrefB, one of them is prioritized, and the output voltages VoA and VoB are controlled to reduce the difference between the output voltages VoA and VoB. Therefore, even with the wire W1A having a small impedance, the voltage at the output terminal ToA can reach VoB. When the voltage of the output terminal ToA reaches VoB, the output current IoutB starts flowing, and the parallel operation is started. At this time, the output currents IoutA and IoutB are controlled substantially equally.

As described above, according to the present embodiment, the parallel operation is enabled by using the voltage drop caused by wires W1A and W1B inside the semiconductor package, and the wires have a small impedance, thereby improving load regulation.

If Au wires are used as the wires W1A and W1B, the impedance of the wires becomes relatively large, and low-sensitivity error amplifiers AP1A and AP1B can be used. Also, if Cu wires are used as the wires W1A and W1B, the cost can be reduced.

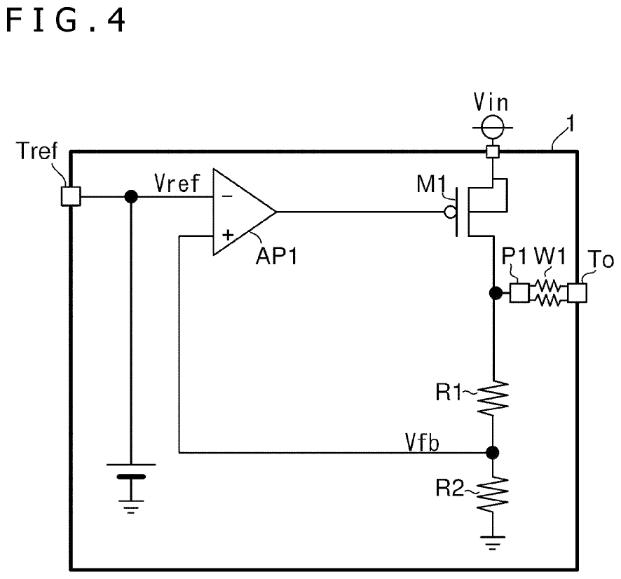

Also, as illustrated in FIG. 4, a plurality of wires W1 may be connected in parallel to an electrode pad P1 and the output terminal To. This allows the wire impedance to be reduced, thereby improving load regulation.

It should be noted that, if the reference voltages VrefA and VrefB can be adjusted as described later, it is not necessary to connect the reference voltage terminals TrefA and TrefB to each other externally.

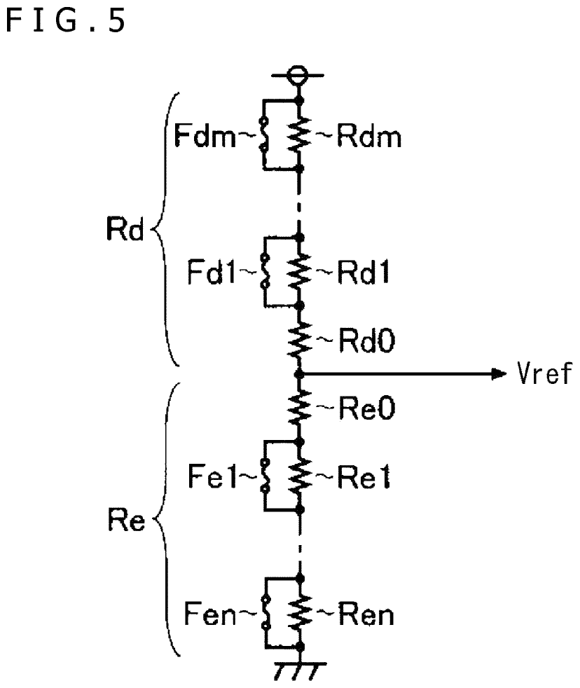

FIG. 5 is a diagram illustrating an example of a configuration for adjusting a reference voltage Vref by using fuses. As illustrated in FIG. 5, a variable resistor Rd includes resistors Rd0 to Rdm connected to one another in series between a lead-out terminal of the reference voltage Vref and a power supply terminal, and trimming fuses Fd1 to Fdm connected in parallel to the resistors Rd1 to Rdm, respectively. In addition, a variable resistor Re has resistors Re0 to Ren connected to one another in series between the lead-out terminal of the reference voltage Vref and the ground terminal, and trimming fuses Fe1 to Fen connected in parallel to the resistors Re1 to Ren, respectively.

With this configuration, the resistance ratio of the variable resistors Rd and Re (and hence the voltage value of the reference voltage Vref) can be adjusted by suitably blowing the fuses Fd1 to Fdm and Fe1 to Fen with a laser.

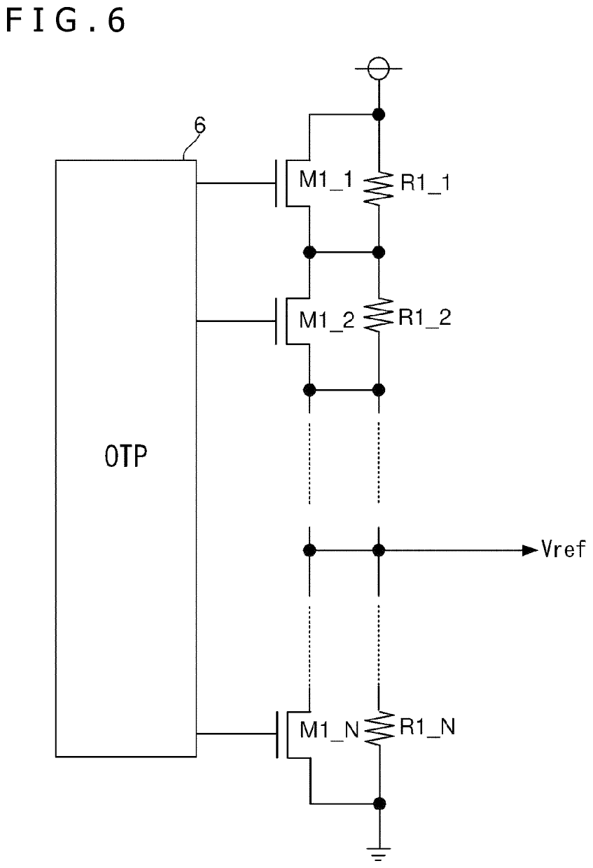

FIG. 6 is a diagram illustrating an example of a configuration for adjusting the reference voltage Vref by using a one time programmable (OTP) memory. An OTP memory 6 illustrated in FIG. 6 is a memory that allows writing thereinto only once. A plurality of resistors, i.e., N resistors R1_1 to R1_N in this example, are connected to one another in series between the power supply terminal and the ground terminal. A plurality of bypass switches, i.e., N bypass switches M1_1 to M1_N in this example, are connected in parallel to the resistors R1_1 to R1_N, respectively. The reference voltage Vref is drawn from the middle of the resistors R1_1 to R1_N and the bypass switches M1_1 to M1_N.

The on-state and off-state of the bypass switches M1_1 to M1_N are switched according to the data written in the OTP memory 6, and the reference voltage Vref is adjusted by setting the voltage dividing ratio.

### 4. Others

It should be noted that, in addition to the above-described embodiment, the various technical features related to the present disclosure can be modified in various ways without departing from the gist of the technical creation. That is, the above-described embodiment should be considered as an example and not restrictive in all respects, and it should be understood that the technical scope of the present disclosure is not limited to the above-described embodiment and includes all changes that fall within the meaning and scope equivalent to the scope of claims. Moreover, the respective embodiments may appropriately be combined and implemented as long as there is no contradiction.

### 5. Additional Notes

As described above, for example, a power supply system (5) according to the embodiment of the present disclosure includes a plurality of linear power supply devices (1A). Each of the linear power supply devices includes an output transistor (M1A) having a first main electrode that is connectable to an application terminal of an input voltage (Vin) and a second main electrode that is connectable to a first feedback resistor (RIA), the first feedback resistor and a second feedback resistor (R2A) being connected to each other in series, an error amplifier (AP1A) to which a reference voltage (VrefA) and a feedback voltage (VfbA) that is generated at a node to which the first feedback resistor and the second feedback resistor are connected are input, the error amplifier being capable of driving a control terminal of the output transistor, an output terminal (ToA), and an electrode pad (P1A). The electrode pad is connected to a node to which the second main electrode and the first feedback resistor are connected. The electrode pad and the output terminal are connected to each other by a wire (W1A). The output terminals of the linear power supply devices are connectable in common to a load (RL).

Further, in the first configuration, a configuration (second configuration) in which the linear power supply devices (1A) further include reference voltage terminals (TrefA) each connected to an application terminal of the reference voltage (VrefA), and the reference voltage terminals are externally connectable to each other may be adopted.

Further, in the first or second configuration, a configuration (third configuration) in which the wire (W1A) includes an Au wire may be adopted.

Further, in any one of the first to third configurations, a configuration (fourth configuration) in which the wire (W1A) includes a Cu wire may be adopted.

Further, in any one of the first to fourth configurations, a configuration (fifth configuration) in which the wire (W1A) includes wires connected in parallel to the electrode pad (P1A) and the output terminal (ToA) may be adopted.

Further, in any one of the first to fifth configurations, a configuration (sixth configuration) in which the reference voltage (VrefA) is able to be adjusted by voltage dividing resistors (Rd1 to Rdm, and Re1 to Ren) to which fuses (Fd1 to Fdm, and Fe1 to Fen) that are able to be blown by a laser are connected in parallel may be adopted.

Further, in any one of the first to fifth configurations, a configuration (seventh configuration) in which the reference voltage (VrefA) is able to be adjusted by switching bypass switches (M1_1 to M1_N) connected in parallel to voltage dividing resistors (R1_1 to R1_N), according to data written in an OTP memory (6), may be adopted.

The present disclosure can be used for a power supply system mounted on various devices.

With the power supply system according to the embodiment of the present disclosure, it is possible for the linear power supply devices connected in parallel to effectively perform the parallel operation.

What is claimed is:

1. A power supply system comprising:
a plurality of linear power supply devices, each of which includes
an output transistor having a first main electrode that is connectable to an application terminal of an input voltage and a second main electrode that is connectable to a first feedback resistor, the first feedback resistor and a second feedback resistor being connected to each other in series,
an error amplifier to which a reference voltage and a feedback voltage that is generated at a node to which the first feedback resistor and the second feedback resistor are connected are input, the error amplifier being capable of driving a control terminal of the output transistor,
an output terminal, and
an electrode pad,
the electrode pad being connected to a node to which the second main electrode and the first feedback resistor are connected,
the electrode pad and the output terminal being connected to each other by a wire, wherein
the output terminals of the linear power supply devices are connectable in common to a load.

2. The power supply system according to claim 1 wherein
the plurality of linear power supply devices further include reference voltage terminals each connected to an application terminal of the reference voltage, and
the reference voltage terminals are externally connectable to each other.

3. The power supply system according to claim 1 wherein
the wire includes an Au wire.

4. The power supply system according to claim 1 wherein
the wire includes a Cu wire.

5. The power supply system according to claim 1 wherein
the wire includes wires connected in parallel to the electrode pad and the output terminal.

6. The power supply system according to claim 1 wherein
the reference voltage is able to be adjusted by a voltage dividing resistor to which a fuse that is able to be blown by a laser is connected in parallel.

7. The power supply system according to claim 1 wherein
the reference voltage is able to be adjusted by switching a bypass switch connected in parallel to a voltage dividing resistor, according to data written in a one time programmable memory.
